(19) United States
(12) Patent Application Publication
(10) Pub. No.: US 2020/0191002 A1
(43) Pub. Date: Jun. 18, 2020

(54) SUPERALLOY TURBINE PART AND ASSOCIATED METHOD FOR MANUFACTURING BY BOMBARDMENT WITH CHARGED PARTICLES

(71) Applicant: SAFRAN, Paris (FR)

(72) Inventors: Amar SABOUNDJI, Moissy-Cramayel (FR); Virginie JAQUET, Moissy-Cramayel (FR)

(21) Appl. No.: 16/611,134

(22) PCT Filed: May 7, 2018
(86) PCT No.: PCT/FR2018/000109

§ 371 Date: Nov. 5, 2019

(30) Foreign Application Priority Data
May 5, 2017 (FR) 17/00488

(51) Int. Cl. F01D 5/28; C23C 14/34; C23C 14/08; C23C 14/50; C23C 14/02

(52) U.S. Cl. CPC F01D 5/288; C23C 14/3471; C23C 14/081; F05D 2230/313; C23C 14/025; F05D 2300/175; C23C 14/505

(57) ABSTRACT

The invention relates to a turbine part, such as a turbine blade or a distributor fin, for example, comprising a substrate made of a monocrystalline nickel superalloy, a metal sublayer covering the substrate, and a protective layer of metal oxide covering the sublayer, characterised in that the metal sublayer has one surface in contact with the protective layer and the surface has a mean roughness of less than 1 μm.

### FIELD OF THE INVENTION

The invention concerns a turbine component, such as a turbine blade or a nozzle guide vane, for example, used in aeronautics.

### STATE OF THE ART

In a turbojet, the exhaust gases generated by the combustion chamber can reach high temperatures, above 1200° C. or even 1600° C. The turbojet components in contact with these exhaust gases, such as turbine blades for example, must therefore be able to maintain their mechanical properties at these high temperatures.

To this end, it is known to fabricate certain components of the turbojet from “superalloy”. Superalloys are a family of high-strength metal alloys that can work at temperatures relatively close to their melting temperatures, typically 0.7 to 0.8 times their melting temperatures.

In order to strengthen the thermal resistance of these superalloys and protect them against oxidation and corrosion, it is known to cover them with a coating that acts as a thermal barrier.

FIG. 1 is diagram of a section of a turbine component 1, for example a turbine blade or a nozzle guide vane. The component 1 includes a single-crystal metallic superalloy substrate 2 covered with a thermal barrier 10.

FIG. 2 is a microphotograph illustrating a section of a part of the thermal barrier 10 of the turbine component 1, covering the substrate 2; the black rectangle in FIG. 2 is a scale bar corresponding to a length of 50 μm. The thermal barrier 10 comprises a metallic bond coat 3, a protective layer 4 and a thermally insulating layer 5. The metallic bond coat 3 covers the metallic superalloy substrate 2. The metallic bond coat 3 is itself covered with the protective layer 4, formed by thermal oxidation of the metallic bond coat 3 (the protective layer is a thermally grown oxide, or TGO). The protective layer 4 protects the superalloy substrate from corrosion and/or oxidation. The thermally insulating layer 5 covers the protective layer 4. The thermally insulating layer 5 can be made of ceramic, for example yttriated zirconia. The metallic bond coat 3 provides a bond between the surface of the superalloy substrate and the protective layer.

During the manufacture of the thermal barrier, it is known to remove the oxides formed on the surface of the bond coat after the deposition of the bond coat. These oxides are formed in contact with the ambient atmosphere and are unstable or metastable when using the turbine component.

To this end, it is known to sandblast the outer surface of the metallic bond coat. Sandblasting allows the oxides formed on the surface of the bond coat to be removed after the bond coat has been deposited.

However, when a TGO is formed on the bond coat after a sandblasting step according to a known method:
impurities are transported to the surface of the bond coat. These impurities are incorporated into the protective layer during the formation of the protective layer by oxidation;
the grain size of the TGO is heterogeneous. The protective layer has in particular small grains (for example less than 1 μm in size), which are known to reduce the corrosion and oxidation resistance of thermal barriers, as well as the adhesion of the protective layer to the bond coat;
different allotropic phases can coexist in the protective layer. In the case of an alumina TGO, it is known that under component conditions of use, at high temperature, the different phases of the α phase are transformed into the α phase by changing volume. This variation in volume leads to tensile stresses and cracks in the TGO, promoting its flaking. Thus, the service life of the thermal barrier is significantly reduced;
the growth kinetics of the TGO is different on different parts of the metallic bond coat. This disparity in the growth kinetics of the TGO leads to mechanical stresses in the TGO when using the thermal barrier and a decrease in its service life.

### SUMMARY OF THE INVENTION

An aim of the invention is to offer a solution to effectively protect a superalloy turbine component from oxidation and corrosion while offering a longer service life than with known thermal barriers.

This aim is achieved in the context of the present invention by a process for manufacturing a turbine component comprising:

a nickel-based single-crystal superalloy substrate,

a metallic bond coat covering the substrate, and

a protective metal oxide layer covering the bond coat, the process comprising the steps of:

a) charged-particle bombardment of a surface of the metallic bond coat, then
b) formation of the protective layer on the surface bombarded in step a).

As the bond coat is bombarded with charged particles, it is possible to obtain an etched surface of the metallic bond coat in contact with the protective layer with a roughness lower than the roughness generally obtained by conventional mechanical sandblasting techniques. In addition, the roughness obtained is more homogeneous. This results in the protective layer growing at a homogeneous kinetics during its formation, which avoids mechanical stresses during the use of the component, causing the protective layer to flake off.

The invention is advantageously complemented by the following features, taken individually or in any one of their technically possible combinations:

the charged-particle bombardment step is carried out by a plasma;

the process comprises a step of vapour-phase deposition of the metallic bond coat on the substrate before step a);

the component is heated, under vacuum, to a temperature above 1000° C., between steps a) and b);

the component is heated between 800° C. and 1200° C. between the deposition of the metallic bond coat and step a).
the component is rotated during step a);
the component is kept under vacuum between steps a) and b).
the component is heated to a temperature above 1000° C. during step b);
step a) is carried out in a first vacuum chamber, step b) is carried out in a second vacuum chamber, and the component is transported, between steps a) and b), from the first chamber to the second chamber in a passage, maintained under vacuum, connecting the two chambers.

The invention also concerns a turbine component comprising:

a nickel-based single-crystal superalloy substrate,

a metallic bond coat covering the substrate, and

a protective metal oxide layer covering the bond coat,

characterized in that the metallic bond coat has a surface in contact with the protective layer and in that the surface has an average roughness of between 100 nm and 1 μm.

The invention is advantageously complemented by the following features, taken individually or in any one of their technically possible combinations:
the standard deviation of the surface roughness is less than 20% of the mean surface roughness;
the protective layer comprises a layer of alumina in the α phase.

### PRESENTATION OF THE DRAWINGS

Other features and benefits will also emerge from the following description, which is purely illustrative and not limiting, and should be read in conjunction with the appended figures, among which:

FIG. 1 is a diagram of a section of a turbine component, for example a turbine blade or a nozzle guide vane;

FIG. 2 is a microphotograph showing a section of a part of the thermal barrier of the turbine component;

FIG. 3 illustrates a process for manufacturing a turbine component;

FIG. 4 is a diagram of a section of a part of a turbine component;

FIG. 5 is a microphotograph showing the surface of the metallic bond coat in contact with the protective layer;

FIG. 6 shows a device for deposition of the metallic bond coat;

FIG. 7 shows a device for charged particle-bombardment of the metallic bond coat;

FIG. 8 shows a device to keep the turbine component under vacuum between a step of etching the metallic bond coat and a step of forming the protective layer.

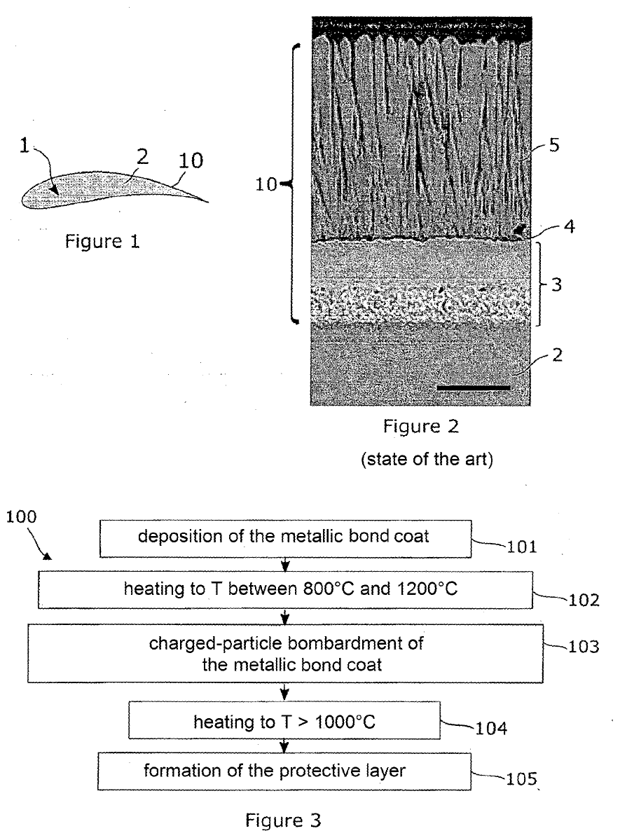

### DEFINITIONS

The term “superalloy” refers to a complex alloy with, at high temperature and high pressure, very good resistance to oxidation, to corrosion, to creep and to cyclic stresses (particularly mechanical or thermal). Superalloys have a particular application in the fabrication of components used in aeronautics, such as turbine blades, because they are a family of high-strength alloys that can work at temperatures relatively close to their melting points (typically 0.7 to 0.8 times their melting temperatures).

The “base” of the superalloy refers to the main metal component of the matrix. In most cases, superalloys include an iron, cobalt, or nickel base, but also sometimes a titanium or aluminium base.

“Nickel-based superalloys” have the advantage of offering a good compromise between oxidation resistance, breaking strength at high temperature and weight, which justifies their use in the hottest parts of turbojets.

The term “vacuum” refers to a primary, medium or high vacuum, i.e. characterized by a pressure between 10⁻³ and 5 mbar. Such a vacuum can be adapted to charged-particle bombardment, for example by the formation of a plasma, at room temperature. The plasma can be argon plasma.

α-Alumina is an allotropic variety of alumina corresponding to corundum, with a rhombohedral crystal structure. An α-alumina layer can be formed by several α-alumina grains, each of the grains delimiting an α-crystalline phase.

Roughness generally refers to a measure of surface condition representative of deviations in the normal direction of the mean plane locally tangent to the surface under consideration. Average roughness, Rₐ, is the arithmetic mean of the norm of the deviations of a surface from the average surface, or:

$${R}_{a} = \frac{1}{n} {\sum }_{i = 1}^{n} \vert {y}_{i} \vert \qquad ( 1 )$$

where yᵢ is a measure of a deviation of the surface from the average surface.

Roughness homogeneity refers to a roughness dispersion smaller than a reference dispersion, characterized and/or measured by a standard deviation of the roughness of a surface of less than 20% of the average roughness.

### DETAILED DESCRIPTION OF THE INVENTION

With reference to FIG. 3, the manufacturing process 100 for a turbine component comprises the following steps.

In a first step 101 of the manufacturing process of the component 1, a metallic bond coat 3 is applied to a single-crystal nickel-based substrate 2. For example, one or more metal layers containing nickel and/or aluminium can be deposited by physical-vapour deposition (PVD). Such deposition may be carried out by sputtering, and/or by any other known method of PVD.

In a second step 102 of the process, the substrate with the metallic bond coat is heated to a temperature T between 800° C. and 1200° C. This heat treatment causes the metal ions of the bond coat 3 to diffuse into the substrate 2 to form an interdiffusion zone, allowing a better oxidation resistance during the use of the component.

In a third step 103 of the process, a surface of the metallic bond coat 3 is bombarded with charged particles. These particles can be ions, such as argon ions, and/or electrons. For example, a surface of the metallic bond coat 3 can be etched with plasma 7, i.e. using a plasma 7. The substrate with a metallic bond coat may be placed in a vacuum chamber, in which a continuous flow of one or more gases supplying the chemical element(s) composing the plasma is controlled. In general, one or more gases are used for metal etching. Advantageously, argon or oxygen is used. This charged-particle bombardment step removes the metastable oxides formed natively on the surface 16 of the bond coat 3.

Thus, the surface roughness 16 may be smaller than by using known methods of the prior art, such as sandblasting and electrochemical etching. For example, the surface 16 of the metallic bond coat 3 has an average roughness Rₐ of less than 1 μm, preferably less than 500 nm and preferably between 100 nm and 300 nm.

The use of charged-particle bombardment also makes it possible to etch the entire surface 16 of the component in a homogeneous way. This effect is particularly suitable for components 1 with complex geometry. For example, the standard deviation of the roughness on the surface 16 of plasma-etched bond coat 3 is less than 500 nm, preferentially less than 300 nm and preferentially less than 100 nm.

In general, the charged-particle bombardment of step 103 can be carried out by any ionic and/or electronic bombardment method that engraves a metal surface with a roughness Rₐ of less than 1 μm. It can also be performed using a femtosecond laser.

Advantageously, the component 1 is rotated during the charged-particle bombardment step 103. To this end, the component 1 can be arranged in a drum in the enclosure or on a rotating support. The rotation of the component increases the homogeneity of the roughness of the surface 16 of the bond coat 3.

As the charged-particle bombardment does not cause any mechanical contact during etching, the transport of impurities on the surface 16 of the bond coat 3 is avoided.

In a fourth step 104 of the process, the component is heated, preferably under vacuum, to a temperature above 1000° C. Thus, plasma atoms, such as argon atoms, possibly adsorbed on the surface 16 of the metallic bond coat 3, are removed or transported away from the component.

In a fifth step 105 of the process, the protective layer 4 is formed on the bombarded surface 16 of the metallic bond coat 3. The surface 16 can be a surface plasma-etched in step 103 of the process. The protective layer 4 is advantageously only composed of α-alumina. To this end, the component is heated in an atmosphere containing oxygen to a temperature above 1000° C., so as to form a protective layer 4 by thermal oxidation. Preferentially, the temperature of 1000° C. is reached in less than ten minutes and preferably in less than five minutes, in order to avoid the formation of metastable oxide on the metallic bond coat 3.

The roughness Rₐ of the surface 16 of the metallic bond coat 3, which is small compared to the usual roughness values, makes it possible to form a protective layer 4 comprising α-alumina grains whose size is greater than the α-alumina grains of the protective layers produced according to known methods. The protective layer 4 can for example include a layer of alumina in the α phase. This layer can be formed of grains of average size, in a plane locally tangent to the surface 16, greater than 50 μm. The increase in α-alumina grain size increases the service life of the thermal barrier. The protective layer 4 may also include a layer of alumina exclusively in the α phase.

In addition, the homogeneity of the roughness of the surface 16 of the charged-particle bombarded metallic bond coat 3 makes it possible to form the protective layer 4 at a constant kinetics on the surface 16 of the metallic bond coat 3. Thus, the protective layer 4 formed has substantially constant mechanical properties and thickness on the surface 16 of the metallic bond coat 3, which avoids mechanical stresses during use of the component, causing the protective layer 4 to flake.

All the steps of the process can advantageously be carried out under vacuum, or in general, without exposing the component to the ambient atmosphere. In particular, the component can be kept under vacuum between steps 103 and 105 of the process. This prevents the formation of unstable and/or metastable oxide on the surface 16.

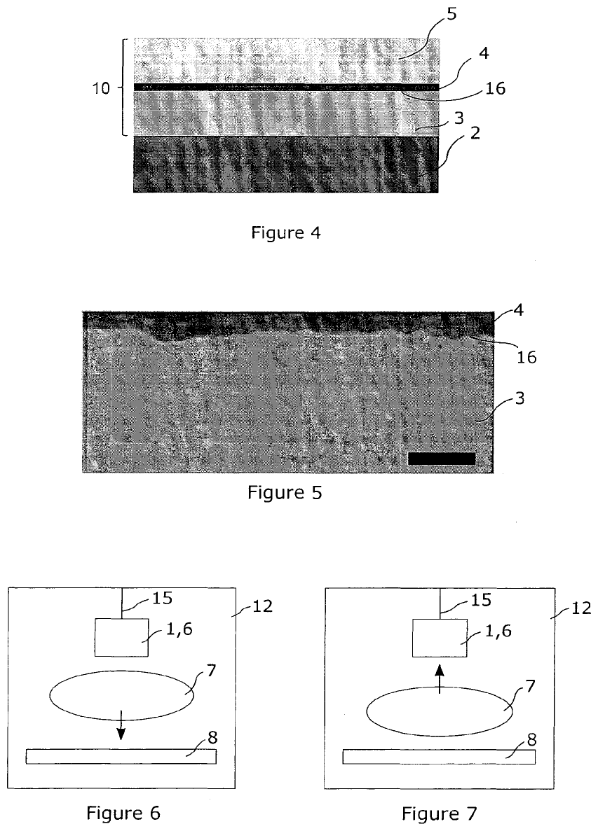

FIG. 4 is a diagram of the section of a part of the turbine component 1 obtained by a process according to the process of FIG. 3. The turbine component 1 is for example a turbine blade, a nozzle guide vane or any other turbine element, component or part. It comprises a single-crystal nickel-based superalloy substrate 2, a metallic bond coat 3 covering the substrate 2 and a protective metal oxide layer 4 covering the bond coat 3. A thermally insulating layer 5 can for example cover the protective layer 4. The thermal barrier 10 includes metallic bond coat 3, the protective layer 4 and thermally insulating layer 5. The metallic bond coat 3 has a surface 16 in contact with the protective layer 4 with a roughness of less than 1 μm, preferentially less than 500 nm and preferentially between 100 and 300 nm.

FIG. 5 is a microphotograph of a detail of a turbine component 1. The black rectangle in FIG. 5 is a scale bar corresponding to 5 μm. The component consists of a protective metal oxide layer 4 covering a metallic bond coat 3. In this embodiment of the invention, the metallic bond coat 3 was plasma etched, then a protective layer 4 was formed on the metallic bond coat 3.

With reference to FIG. 6, the PVD deposition corresponding to step 101 can be performed inside an enclosure 12 containing component 1 and one or more target(s) 8 corresponding to the material(s) to be deposited. The component 1 shown in FIG. 6 can be a turbine blade 6, a nozzle guide vane, or any other element, component or part of a turbine. The superalloy substrate 2 can be polarized by an electrical connection 15 connected to an electrical potential generator. Under the application of a positive potential difference between the target(s) 8 and the substrate 2, an argon plasma 7 can be formed, whose positive species are attracted to the cathode (target 8) and collide therewith. The atoms of the target(s) 8 are sputtered and then condense on said component to form the metallic bond coat(s) 3. Preferably, the deposition conditions are as follows:

heating during deposition: from 100 to 900° C.;

pressure: from 0.1 Pa to 1 Pa;

power density: 2 to 15 W/cm²;

polarization: from 0 to 400 V.

The ion bombardment is carried out for 10 to 30 minutes.

With reference to FIG. 7, the charged-particle bombardment, for example by means of a plasma 7, corresponding to step 103, can be carried out inside an enclosure 12 containing the component 1 and one or more targets 8 corresponding to the material(s) to be deposited. The enclosure can be the one used in step 101 shown in FIG. 6. The superalloy substrate 2 can be polarized by an electrical connection 15 connected to an electrical potential generator. Under the application of a negative potential difference between the target(s) 8 and the substrate 2, an argon plasma 7 can form, whose positive species are attracted to the cathode (turbine component) and collide therewith. Thus, the surface 16 of the metallic bond coat 3 can be etched. Preferably, the deposition conditions are as follows:

pressure: from 0.1 Pa to 1 Pa;

power density: 2 to 15 W/cm²;

polarization: from 0 to −400 V.

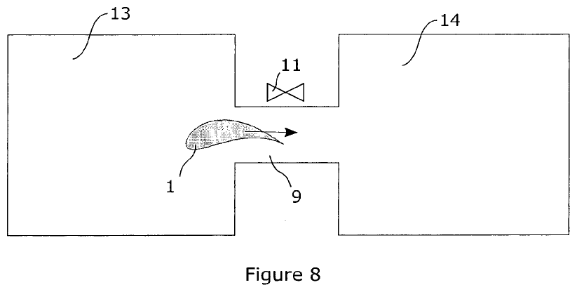

With reference to FIG. 8, the step 103 of manufacturing the component can be carried out in a first enclosure 13. The component can be transported from the first enclosure to a second enclosure 14, in which step 105 is carried out, in a passage 9 maintained under vacuum, connecting the two enclosures 13, 14. The passage can be delimited by a channel, a conduit and/or a pipe. Thus, the component can be kept under vacuum between steps 103 and 105 in order to avoid the formation of metastable or unstable oxide before the formation of the protective layer 4 in step 105. The passage can include a valve 11, allowing vacuum control in only one of the first or second chambers, depending on the manufacturing step of the component. The opening of valve 11 is adapted to the transport of the turbine component from the first enclosure to the second enclosure.

1. A process for manufacturing a turbine component comprising:
a single-crystal nickel-based superalloy substrate,
a metallic bond coat covering the substrate, and
a protective metal oxide layer covering the bond coat,
the process comprising the steps of:
a) charged-particle bombardment of a surface of the metallic bond coat in such a way that the surface has an average roughness of between 100 nm and 1 μm, then
b) formation of the protective layer on the surface bombarded in step a).

2. The process of claim 1, wherein the charged-particle bombardment is carried out by a plasma.

3. The process of claim 1, comprising a step of vapour-phase deposition of the metallic bond coat on the substrate before step a) of the process.

4. The process of claim 1, comprising a step of heating the component, under vacuum, to a temperature above 1000° C., between steps a) and b).

5. The process of claim 1, wherein the component is heated to between 800° C. and 1200° C. between the deposition of the metallic bond coat and step a).

6. The process of claim 1, wherein the component is rotated during step a).

7. The process of claim 1, wherein the component is kept under vacuum between steps a) and b).

8. The process of claim 1, wherein the component is heated to a temperature above 1000° C. during step b).

9. The process of claim 1, wherein step a) is carried out in a first vacuum chamber, step b) is carried out in a second vacuum chamber, and wherein the component is transported, between steps a) and b), from the first chamber to the second chamber in a passage, maintained under vacuum, connecting the two chambers.

10. A turbine component comprising:
a single-crystal nickel-based superalloy substrate,
a metallic bond coat covering the substrate, and
a protective metal oxide layer covering the bond coat,
wherein the metallic bond coat has a surface in contact with the protective layer and the surface has an average roughness of between 100 nm and 1 μm.

11. The turbine component of claim 10 wherein the standard deviation of the surface roughness is less than 20% of the mean surface roughness.

12. The turbine component of 10, wherein the protective layer comprises a layer of alumina in the α phase.
